(19) United States
(12) Patent Application Publication
(10) Pub. No.: US 2010/0140792 A1
(43) Pub. Date: Jun. 10, 2010

(54) GRAPHITE NANOPLATELETS FOR THERMAL AND ELECTRICAL APPLICATIONS

(75) Inventors: Robert C. Haddon, Riverside, CA (US); Mikhail E. Itkis, Riverside, CA (US); Palanisamy Ramesh, Riverside, CA (US); Aiping Yu, Riverside, CA (US); Elena Bekyarova, Riverside, CA (US); Kimberly Worsley, Riverside, CA (US)

Correspondence Address: KNOBBE MARTENS OLSON & BEAR LLP, 2040 MAIN STREET, FOURTEENTH FLOOR, IRVINE, CA, 92614, US

(73) Assignee: The Regents of the University of California, Oakland, CA (US)

(21) Appl. No.: 12/513,151

(22) PCT Filed: Oct. 31, 2007
(86) PCT No.: PCT/US07/83252

§ 371 Date: Feb. 8, 2010

Related U.S. Application Data
(60) Provisional application No. 60/863,774, filed on Oct. 31, 2006.

(51) Int. Cl. H01L 23/36; C01B 31/04; C09K 5/00; B32B 9/00

(52) U.S. Cl. 257/713; 423/448; 252/74; 428/402; 977/700; 977/742; 257/E23.101

(57) ABSTRACT

This disclosure concerns a procedure for bulk scale preparation of high aspect ratio, 2-dimensional nano platelets comprised of a few graphene layers, Gₙ. n may, for example, vary between about 2 to 10. Use of these nano platelets in applications such as thermal interface materials, advanced composites, and thin film coatings provide material systems with superior mechanical, electrical, optical, thermal, and antifriction characteristics.

### CROSS-REFERENCE TO RELATED APPLICATIONS

This application claims the benefit of priority under 35 U.S.C. §119(e) of U.S. Provisional Application No. 60/863,774 filed on Oct. 31, 2006, entitled GRAPHENE NANOPLATELETS FOR THERMAL AND ELECTRICAL APPLICATIONS, the entirety of which is incorporated herein by reference.

### STATEMENT REGARDING FEDERALLY SPONSORED R&D

This invention was made with Government support under Contract Numbers H94003-04-2-0404-P00002 and H94003-05-2-0505 awarded by the Department of Defense (DOD). The Government has certain rights in this invention.

### BACKGROUND

1. Field

Embodiments of the present disclosure relate to composite materials and, in particular, concerns the preparation of polymer composite materials using graphite nano-platelets (GNPs) which are obtained by the controlled thermal exfoliation of graphite intercalation compounds.

2. Description of the Related Art

Thermal interface materials (TIMs) are commonly required to facilitate the transfer of thermal energy from electronic components to a heat sink. Heat dissipation from electronic components is an increasingly important problem because of the rapid growth of high-performance, high power computer processing units. Microprocessors, integrated circuits and other sophisticated electronic components operate efficiently only within certain well defined temperature limits. Excessive heat generated during operation can degrade the performance and reliability of the overall system and can lead to system failure. Besides transferring heat, prospective TIMs should also substantially dissipate at least a portion of the thermomechanical stresses resulting from the mismatch of the thermal expansion of the different materials. In general, low coefficients of thermal expansion (CTE) are preferred for these applications.

Commercial TIMs are typically based on composites of polymers, greases or adhesives which are filled with thermally conductive particles such as silver, alumina or silica. However, these systems typically require a filler volume fraction of about 70% in order to achieve thermal conductivity values in the range of approximately 1-5 W/mK.

Several forms of carbon materials have been used as fillers in composite materials. For example, carbon nanotubes (CNTs) have emerged as an efficient filler in polymer matrices owing to their superior mechanical strength, electrical conductivity, thermal conductivity (˜3000 W/mK along the CNT axis), and high aspect ratio. The high cost of CNTs, however, is inhibiting broad based industrial applications of CNTs. Furthermore, despite significant recent progress, carbon nanotube based composites do not reach the theoretically predicted level of thermal conductivity, which is usually attributed to the high thermal interface resistance between the nanotubes and the polymer matrix.

From the foregoing, it may be appreciated that there is a need for improved composite materials for use in thermal interface materials

### BRIEF DESCRIPTION OF THE DRAWINGS

FIGS. 1A-B illustrate embodiments of edge-on micrographs of graphite flakes; (A) natural graphite flakes; (B) intercalated graphite flakes exfoliated by thermal shock at temperatures of about 200 (GNP-200), 400 (GNP-400), and 800° C. (GNP-800);

FIG. 2 is a scanning electron micrograph of one embodiment of a graphite flake exfoliated at about 800° C.;

FIGS. 3A-C are atomic force microscopy (AFM) scans illustrating embodiments of the geometry of the graphite flakes after dispersion; (A) GNP-200; (B) GNP-400; (C) GNP-800;

FIGS. 4A-4C are transmission electron micrographs of cross-sections of the GNPs illustrating embodiments of layers of GNP-200, GNP-400, and GNP-800 embedded within an epoxy matrix;

FIG. 5 is a schematic illustration of a conduction pathway in GNP-epoxy composite;

FIG. 6 is a schematic of one embodiment of a substantially transparent, conducting thin film of GNP;

FIG. 7 is a schematic of one embodiment of a conduction pathway in transparent thin-film of GNP;

FIG. 8 is a chart illustrating the results of measurements of thermal conductivity of epoxy and its composites possessing approximately 0.054 volume fraction of carbon materials (graphite in this context refers to powdered natural graphite);

FIG. 9 is a data plot illustrating thermal conductivity enhancements obtained in composites as a function of filler volume fraction, comparing carbon black-epoxy, graphite-epoxy, purified single-walled carbon nanotube-epoxy (p-SWNTs) and GNP-epoxy composites; and

FIG. 10 is a data plot illustrating the electrical conductivities of different GNP-epoxy composites compared to carbon nanotubes, where AP-SWNT and p-SWNT correspond to as-prepared and purified SWNT, respectively.

These and other aspects, advantages, and novel features of the present teachings will become apparent upon reading the following detailed description and upon reference to the accompanying drawings.

### SUMMARY

In an embodiment, the present disclosure provides a method of fabricating graphite nano platelets. The method comprises providing a graphite compound, intercalating the graphite compound by exposure to a plurality of acids, exfoliating the intercalated graphite compound to form graphite nano platelets, where the exfoliation heating rate is varied so as to vary the length to thickness ratio of the graphite nano platelets, and physically separating the graphite nano platelets.

In a further embodiment, the present disclosure provides graphite nano platelets. The graphite nano platelets comprise an intercalated and thermally exfoliated graphite having an average length which varies between about 1.7 to 0.35 μm and an average thickness which varies between about 60 to 1.7 nm. The nano platelets are substantially separated from each other.

In an additional embodiment, the present disclosure provides a graphite nano platelet composite. The composite comprises a polymer and a plurality of graphite nano platelets. The graphite nano platelets comprise intercalated and thermally exfoliated graphite having an average length which varies between about 1.7 to 0.35 μm and an average thickness which varies between about 60 to 1.7 nm. The graphite nano platelets are further substantially separated from each other. The loading fraction of the graphite nano platelet ranges between approximately 0.2 to 50 vol. %, based upon the total volume of the composite.

In a further embodiment, the present disclosure provides a microelectronic package. The microelectronic package comprises a substrate, a thin film present on at least one surface of the substrate, where the thin film comprises a plurality of graphite nano platelets, and an integrated circuit mounted to at least one surface of the substrate. In an embodiment, the graphite nano platelets comprise intercalated and thermally exfoliated graphite having an average length which varies between about 1.7 to 0.35 μm and an average thickness which varies between about 60 to 1.7 nm. In a further embodiment, the thin film is substantially transparent and possesses an average thickness of between approximately 10 nm to 300 nm.

### DETAILED DESCRIPTION OF SOME EMBODIMENTS

Embodiments of the present disclosure provide an economical route to a new class of efficient thermal interface materials (TIMs) which outperform traditional TIMs, while utilizing significantly lower amounts of fillers. These new materials also allow the preparation of stable dispersions of graphite nano-platelets having few graphene layers, facilitating the production of advanced composites and thin film coatings. Additionally, these composites and coatings possess superior mechanical, electrical, optical, thermal, and antifriction characteristics because of the outstanding material properties of the graphene sheets.

In one embodiment, controlled thermal exfoliation natural graphite with subsequent dispersion has been found to produce few graphene layer particles. As discussed in greater detail below, few graphene layer sheets, Gₙ, represent a robust and compelling alternative to single layer graphene (G₁) in the fabrication of advanced composites. The GNPs are prepared using a laboratory procedure and show outstanding mechanical, thermal, and electrical conductivity properties. This technology provides an economical route to a new class of efficient thermal management materials which will find application in modern chip packaging where improved thermal interface materials (TIMs) are required for efficient heat dissipation. In contrast, conventional TIMs are based on polymers, greases or adhesives filled with thermally conductive particles such as silver, alumina or silica which require a filler volume fraction of approximately 70%, in order to achieve thermal conductivity values of 1-5 W/mK. The excellent electrical conductivity of these materials may allow them to find application as conductive coatings, fuel cell components and transparent electrodes.

In one embodiment, the present disclosure provides controlled exfoliation of graphite. The preparation of graphite based, plate-like nanomaterials with desired lateral size, thickness, and aspect ratio is discussed. An advantage of this particular exfoliation method is that it provides control of the shape of the graphite nanomaterials. This method produces thin plate-like material with substantially flat, smooth surfaces. A further advantage of the controlled thermal exfoliation is control of the degree of exfoliation obtained when compared to other methods of solution and chemically based exfoliation.

In another embodiment, the present disclosure provides for the utilization of shear-mixing and ultrasonic bath treatments in a post-exfoliation step. Conventional powdering techniques, such as grinding, result in re-aggregated, compressed sheets due to the flexible nature of the exfoliated graphite. Shear mixing of the exfoliated graphite in various solvents is performed under controlled conditions in order to break the worm-like fibers. Subsequent application of several hours of ultrasonic irradiation results in stable suspensions of the graphene nano-platelets (GNPs). An advantage of the GNP suspensions prepared by this method is the high aspect ratio of the resulting GNPs. Further, the present technique leads to stable suspensions of the GNPs, substantially without the presence of stabilizing agents, surfactants or organic molecules. Nevertheless, this disclosure may also use any of the above mentioned agents to disperse the GNPs in solvents.

In a further embodiment, the present disclosure provides few graphene layer GNPs, in comparison with single graphene layer sheets. The present method provides bulk production of few graphene layer GNPs, Gₙ. In one embodiment, n is less than about 20. In further embodiments, n ranges between about 2 to 10. In additional embodiments, n is about 4. The few graphene layer GNPs are mechanically robust and substantially chemically inert compared to single-layer graphene. Further, in the case of few graphene layer GNPs, the outer layers act as a shielding interface to the matrix, while the pristine inner layers function as a substantially conducting pathway for thermal and electrical transport in a non-scattering environment. It may be understood, however, that the methods described herein may be utilized to form graphite nano platelets having a plurality of graphene sheets, without limiting the embodiments of the disclosure.

In further advantage, the strong oxidation step typically employed to produce single graphene sheets may be avoided and additional functional groups, and surfactants or stabilizing agents, are not required. These functional groups may be added, however, as necessary.

In an additional embodiment, the present disclosure provides a method of in-situ polymerization of GNPs in the polymer matrix. The GNPs are substantially isotropically encapsulated within epoxy matrix by using an in-situ cross-linking technique. The method may be utilized with any volume ratio of GNPs in epoxy-based and other types of polymer matrices in order to form high strength, thermally and/or electrically conducting composites, and thermal interface materials. An advantage of the in-situ polymerization is the dispersion and stabilization of the GNPs in the polymer matrix.

In another embodiment, the present disclosure provides chemical modification of GNP edges or outer layers for controlling the thermal and electrical properties for selected applications. For example, these modifications may include, but are not limited to, chemical modifications to introduce functional groups to the outer layers or edges to engineer the graphene/polymer interface or improve the compatibility with specific solvents. An important advantage of the few graphene layer nano-platelets is the ability to independently control the electrical and thermal properties of composites for a specific application. Edge functionality can be introduced to substantially suppress electrical percolation while enhancing the thermal transport in a route towards very efficient thermal interface materials which are substantially electrically insulating or for the production of composites with high thermal and electrical conductivity.

In a further embodiment, the present disclosure provides thin films of GNPs for transparent conductive coatings for use in large area optoelectronic applications. The GNPs possess the high in-plane electrical conductivity of graphite and high optical transmittance and may be used as a cost effective alternative to indium-tin-oxide coatings, which are widely used in applications requiring a transparent front contact such as light-emitting diodes and photovoltaic cells.

In an additional embodiment, the present disclosure provides fuel cells utilizing GNPs. Due to the high conductivity of the GNPs, their 2 dimensional structure and high surface area they provide a substantially efficient replacement and supplement for various carbon components in fuel cells. The graphitic nano-platelets can improve or replace the carbon cloth and carbon paper that are used as the gas diffusion layer and electrode in fuel cells. The high surface area of the GNPs also makes them strong candidates for utilization as a support for the platinum catalyst in fuel cells in order to reduce the precious metal loading.

In another embodiment, the present disclosure provides hybrid materials composed of GNPs and carbon nanotubes. Highly optimized fillers for composite materials or transparent conductive coatings can be achieved by the preparation of hybrid materials composed of blends of GNPs and carbon nanotubes. The ratio of loading fractions of GNP and nanotubes may be varied as necessary. Enhancement of the electrical, thermal and mechanical performance of the hybrid GNP-carbon nanotube materials can, in certain embodiments, exceed the performance of the sum of individual contributions of the GNPs and carbon nanotubes. Carbon nanotubes provide a flexible mechanical network in which to embed the GNPs and introduce efficient bridges between the GNPs to enhance the thermal and electrical performance.

In an embodiment, the present disclosure provides lubricants comprising, at least in part, graphite nano-platelets. Due to their 2D shape and mechanical, thermal and inert chemical structure the GNPs are an excellent additive for lubricants.

These and other embodiments and advantages of the present disclosure are discussed in detail below.

Graphite, an allotrope of carbon, includes substantially superimposed lamellae of two-dimensional (2D) carbon-carbon covalent networks called graphene (abbreviated G₁). By convention, individual graphene layers are taken to lie in the crystallographic ‘a, b’ plane and are stacked in a substantially perpendicular manner along the crystallographic ‘c’ axis as a result of weak van der Waals forces. The superior electronic properties of graphene have prompted a search for an efficient route to prepare substantially individual, separated graphene sheets.

Chemical processing has already allowed the study of the solution phase properties of single-layer graphene. An alternative chemical process substantially stabilizes the graphene sheets by extensive oxygenation of the framework, disrupting the sp² carbon network. Subsequent reduction is performed to restore the graphene electronic structure. Such chemically produced graphene sheets have been utilized for the fabrication of electrically conductive composites and studies have demonstrated that graphene functions as an efficient network for electrical transport with a very low percolation threshold.

The inter-lamellar space between the charged graphene layers acts as an ideal host for many ionic species. This intercalation process, which may involve acids or alkali metals, leads to graphite intercalation compounds (GICs). Exfoliation of GICs brings about a phase transition of the intercalate and substantially results in an expansion of graphite along the ‘c’ axis. GICs are thermally decomposed to obtain ultra-thin graphite flakes known as exfoliated graphite. Single layer graphene obtained by exfoliating alkali metal-graphite intercalation compounds are found to scroll spontaneously to form graphene nano scrolls. Further, the aspect ratio of single-layer graphene is considerably reduced by the scrolling, while the dimensionality of the material is effectively reduced from 2 to 1.

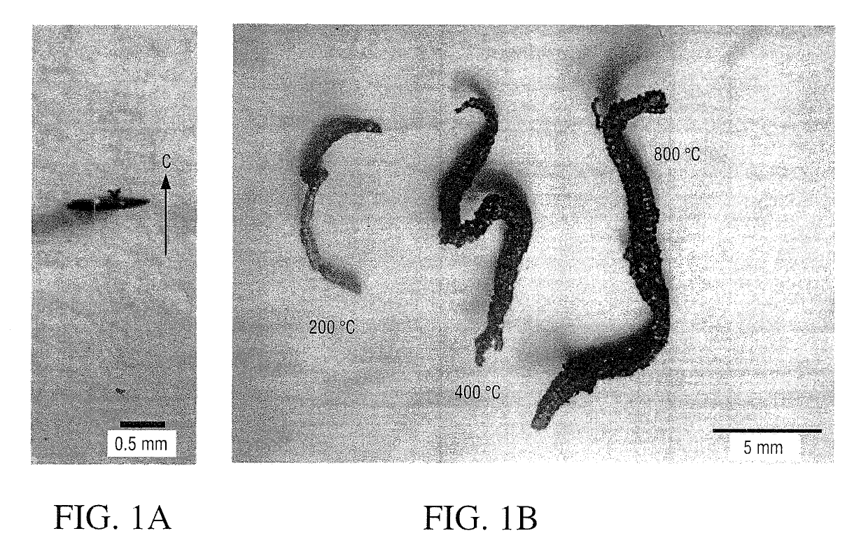

The exfoliation procedure does not in itself lead to individual GNPs, however. This is illustrated by measuring the end-to-end resistance of the exfoliated objects such as those shown in FIGS. 1A-B. Typically these expanded graphite flakes exhibit an electrical resistance of about 10 ohms along their thickness, thus contact is retained between the sheets. Shear-mixing and ultrasonic bath treatments in the post-exfoliation step are performed to complete the production of the GNPs. Conventional powdering techniques, such as grinding, result in re-aggregated, compressed sheets due to the flexible nature of the exfoliated graphite. As discussed below, embodiments of the present disclosure provide a method of shear mixing the exfoliated graphite in various solvents under controlled conditions in order to break the worm-like fibers. Subsequent ultrasonication produces stable GNP suspensions which are suitable starting materials for the fabrication of advanced composites and films.

In one embodiment, graphite is treated with a plurality of concentrated acids in order to provide an intercalated graphite compound. The graphite may be provided in particulate form. Such particles may include any geometric form, including, but not limited to, flakes, fibers, powders, crystals, and combinations thereof. The largest dimension of the graphite particles may range between approximately 20 to 800 μm. In one example, discussed in greater detail below, graphite flakes with an average size of approximately 500 μm (Asbury Graphite Mills Inc., NJ, USA) are employed.

The acid used to treat the graphite compound may comprise a single acid or mixture of acids which is sufficient to intercalate the graphite compound. In one embodiment, the acid comprises an approximately 3:1 mixture of concentrated sulfuric and nitric acid. The graphite compound is exposed to the acid mixture overnight at about room temperature. For example, the graphite flakes may be exposed to the acid mixture for greater than about 8 hours at a temperature of about 23° C. In alternative embodiments, the acid mixture may be heated to a temperature less than about 180° C. It may be further understood, however, that other forms of graphite and other acids may be used. For example, synthetic graphite may be employed.

The intercalated graphite is subsequently filtered, cleaned, and dried prior to further processing. In one embodiment, the intercalated graphite is filtered so as to substantially remove the excess acid. After filtering, the intercalated graphite is washed with distilled water and dried to substantially remove water remaining within the graphite. In one embodiment, the intercalated graphite may be dried in air so as to substantially remove the water. In another embodiment, the intercalated graphite may be air dried for approximately 24 to 120 hours. For example, the intercalated graphite may be air-dried for about 2 days. In further embodiments, the intercalated graphite may be heated at low temperatures, less than approximately 150° C., for approximately 2 to 6 hours in air, to assist the drying process.

The intercalated graphite is then exfoliated by rapid heating. In one embodiment, the intercalated graphite may be heated in an inert environment to temperatures less than or equal to about 1000° C., less than or equal to about 800° C., less than or equal to about 600° C., less than or equal to about 400° C., and about 200° C. over an approximately 2 minute duration. In alternative embodiments, the intercalated graphite may be heated at a rate less than or equal to about 500° C./min, less than or equal to about 400° C./min, less than or equal to about 300° C./min, less than or equal to about 200° C./min, and about 100° C./min. In one embodiment, the intercalated graphite is thermally shocked by an approximately 2 minute, rapid exposure to peak temperatures of approximately 200, 400, and 800° C. in a nitrogen atmosphere, as discussed in greater detail below. Alternative temperatures may be employed as necessary.

Upon thermally shocking the intercalated graphite, the acid trapped between the graphene layers vaporizes, both increasing the volume of the graphite and expanding the graphite along the c-axis. FIGS. 1A-1B show edge view images of natural graphite in the as received condition (FIG. 1A) and after being exfoliated with peak temperatures of approximately 200, 400, and 800° C. These materials are herein referred to as GNP-200, GNP-400, and GNP-800, respectively.

As illustrated in FIG. 1B, after the exfoliation, the volume of the graphite expands significantly and the graphite takes on a substantially worm-like morphology. For example, at an exfoliation temperature of about 200° C., the volume of the graphite particles increases more than about one hundred times. A further increase in volume is obtained up to temperatures of at least about 800° C. Furthermore, the length of the worm-like fiber is found to generally increase with the exfoliation temperature.

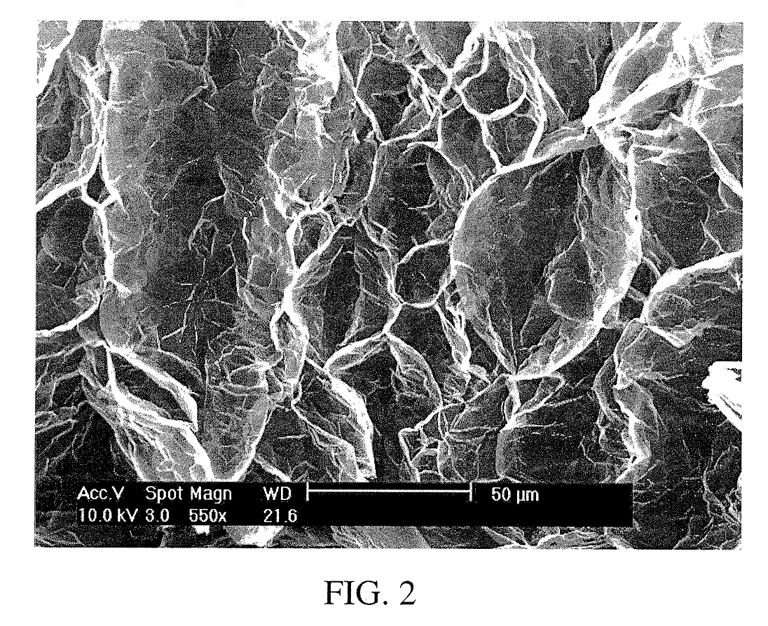

FIG. 2 shows a scanning electron micrograph of a section of graphite exfoliated at 800° C. The micrograph illustrates that large void spaces have been introduced between the thin graphite sheets. Concurrently, however, the sheets still retain a degree of structural integrity, owing to strong van der Waals forces. While not illustrated, the void space between the graphite plates also grows as the temperature of exfoliation is increased. The measured resistance along the length of the fibers is found to be approximately 10 ohms.

Stable dispersions of graphite nano-platelets having high aspect ratios are obtained by shear mixing and ultrasonication of the exfoliated graphite in solvents. Conventional powdering techniques routinely utilized for physical separation such as grinding, can lead to re-aggregation of the nano-platelets into multi-layer, compressed sheets due to the flexible nature of the exfoliated graphite. Therefore, shear mixing and ultrasonication is performed on the expanded, exfoliated graphite in order to physically separate the graphite. In one embodiment, the shear mixing is performed in acetone for at least about 30 minutes, followed by ultrasonication at a sonic power ranging between approximately 45 W and 270 W for up to about 24 hours to obtain a GNP dispersion. In alternative embodiments, the solvent may comprise ethanol, isopropanol, tetrahydrofuran, dimethylformamide and mixtures thereof. The solvent and times of mixing and ultrasonication may be further varied, as necessary.

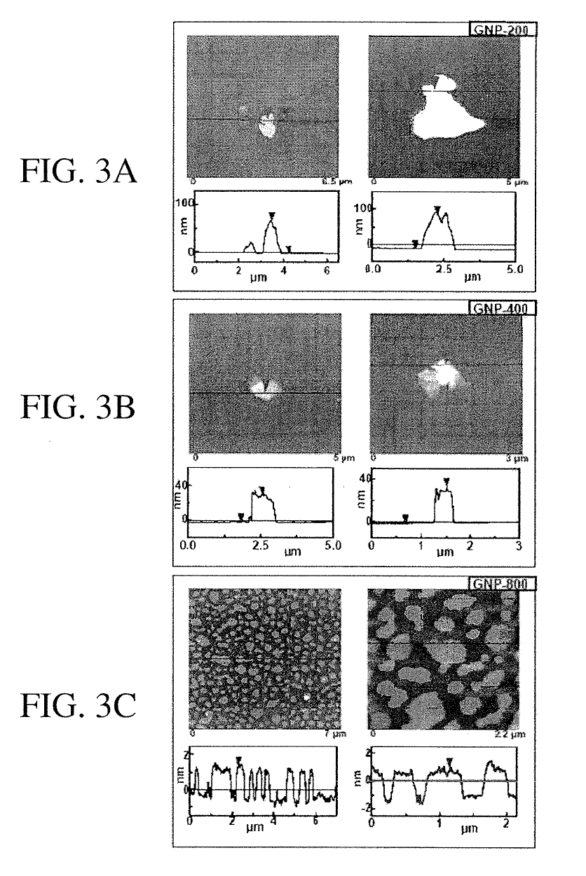

FIGS. 3A-3C show example AFM images of the GNP-200, GNP-400, and GNP-800 materials after exfoliation and subsequent physical separation. Tapping mode AFM images of the GNPs are obtained using a Digital Instruments Nanoscope IIIA. The length (L) is an average diameter of the GNPs in the ‘a, b’ plane, whereas the thickness (t) is an average of the dimension of the GNP along the ‘c’ axis. The approximate average size (L) and thickness (t) of the example nanoparticles after exfoliation at about 200° C. (GNP-200), and processing is about L=1.7 μm and t=60 nm. This represents a reduction in average thickness of the GNPs by about 250 times, compared to the starting graphite particles, due to expansion and exfoliation. Exfoliation at about 400° C. results in a further reduction in size, to about L=1.1 μm and t=25 nm. The GNP-200 and GNP-400 samples demonstrate a substantially wide thickness distribution and the nano-platelets are of irregular shape. In contrast, at an exfoliation temperature of about 800° C., the nano-platelets (GNP-800) are substantially flat, with a narrow thickness distribution centered about approximately t=1.7 nm. This corresponds to substantially full exfoliation of the stage 4 intercalation compound into individually stabilized graphite nano-platelets predominantly containing G₄ stacking motifs, where Gₙ denotes the number of graphene layers in the GNPs. The average size of the GNP-800 material was approximately L=0.35 μm. Further, the average aspect ratio of the GNPs calculated from the AFM images is about 30, 50, and 200 for GNP-200, GNP-400 and GNP-800, respectively.

Advantageously, embodiments of the present disclosure allow for the preparation of graphite nano-platelets with selected aspect ratios. For example, thin, roughly 1.7 nm GNP-800 graphite nano-platelets may be fabricated substantially without chemical functionalization which corresponds to stage 4 graphite (Gₙ, where n≈4). It may be understood, however, that disclosed embodiments may provide GNPs corresponding to selected stages. For example, GNPs having n from about 2 to 10 may be provided.

The GNPs fabricated in this manner may be further encapsulated in epoxy using an in-situ cross linking technique in order to obtain solid GNP-composites. In one embodiment, an epoxy resin comprising diglycidyl ether of bisphenol F (EPON 862) is added to the GNP dispersion. The solvent is removed by heat treatment at approximately 50° C. in a vacuum oven and a curing agent comprising diethyltoluenediamine (EPICURE W) is added to the epoxy-GNP mixture while continuously stirring. The mixture containing the curing agent is subsequently loaded into a stainless steel mold of selected shape, degassed, and heated in vacuum. Heat treatment comprises temperature of about 100° C. for about 2 h, followed by heat treatment at about 150° C. for about 2 h to complete the curing cycle.

A series of composites are prepared having varied GNP loadings. In one embodiment, the loading fraction of the graphite nanoplatelets may range between approximately 0.2 to 50 vol. %, on the basis of the total volume of the composite. In alternative embodiments, the loading fraction of the graphite nanoplatelets is less than about 50 vol. %, less than about 40 vol. %, less than about 30 vol. %, less than about 20 vol. %, less than about 10 vol. %, less than about 5 vol. %, less than about 2 vol. %, and less than about 1 vol. %. Densities of approximately 2.26 g/cm³ (graphite and GNPs), 1.4 g/cm³ (SWNTs), and 1.17 g/cm³ (epoxy) were utilized to calculate the volume fraction using the masses of each of the filler and epoxy. It may be understood that other epoxy resins and curing agents may be utilized in fabrication of the composite.

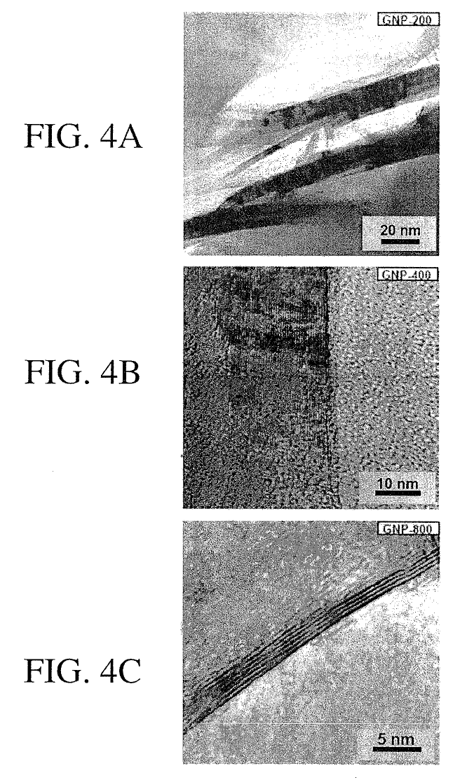

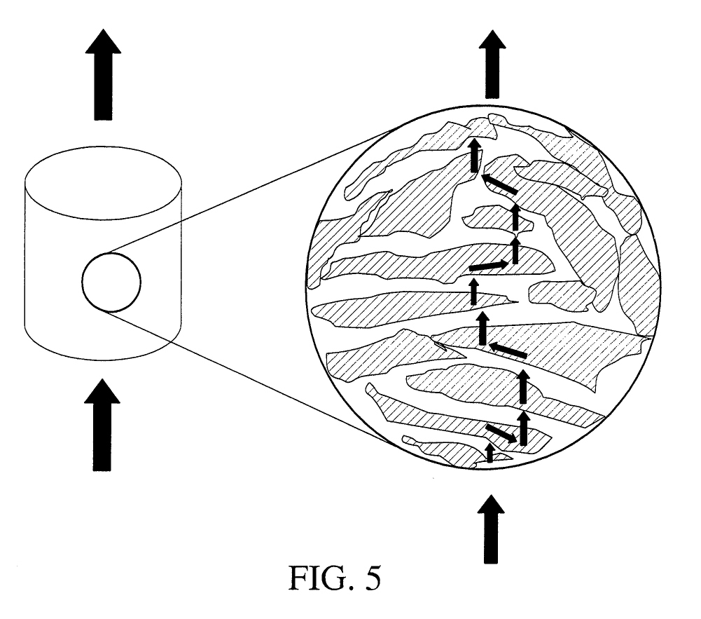

Cross sectional transmission electron microscopy (TEM) images of the GNPs within the epoxy polymer matrix are shown in FIGS. 4A-4C. High resolution TEM was performed using a FEI-Philips CM300 microscope operating at a voltage of about 200 kV. As illustrated in FIGS. 4A-4C, the graphene layers remain substantially exfoliated and stabilized within the polymer matrix. The graphene layers in the GNP-200 and GNP-400 samples are also thicker than those in the GNP-800 material in accord with the AFM measurements. This illustrates that the thermal shock treatment at peak temperatures of about 200° C. and 400° C. lead to higher order structures (Gₙ, where n>10). The TEM analysis further illustrates that the GNPs are embedded within the matrix as isolated plates. These substantially rigid GNPs form a conducting network within the epoxy matrix which may be schematically represented as illustrated in FIG. 5.

In one embodiment, the GNPs may be subsequently treated with nitric acid to introduce oxygen functional groups. Mid—IR spectra of these oxidized GNPs confirm the presence of carboxyl group, which shows a peak between about 1700 and 1750 cm⁻¹. The introduction of the carboxylic acid groups further stabilizes dispersions of the oxidized GNPs in solvents and also enables further functionalization chemistry.

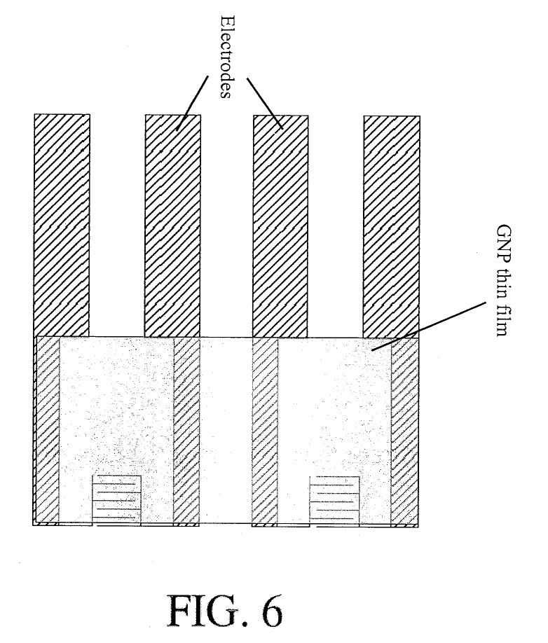

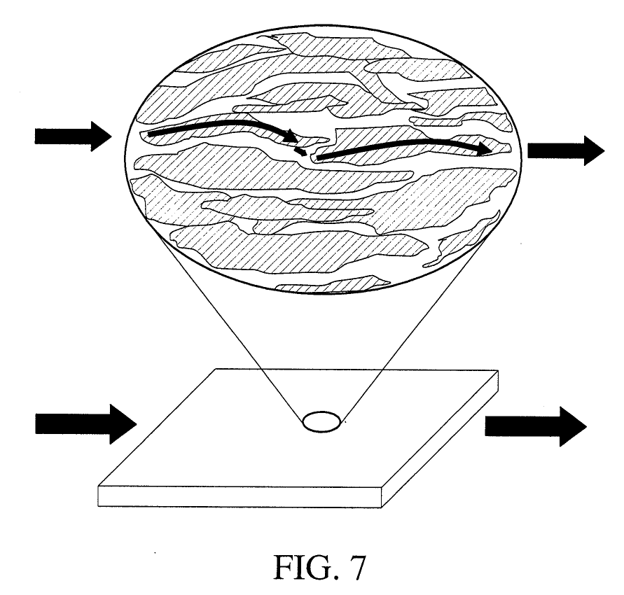

In a further embodiment, a spraying technique may be used to form thin-films of the GNP composites on substrates. FIG. 6 shows a schematic of a one embodiment of a transparent GNP thin film. The GNPs form a substantially continuous, transparent, conducting film with a thickness ranging from approximately 10 nm to 500 nm. FIG. 7 shows a schematic of a conducting pathway within the film.

In an embodiment, the substrates coated with GNP thin films may be employed in microelectronic packages. Microelectronic packages may comprise, in one non-limiting example, integrated circuits, such as microelectronic dies, mounted through electrical connections to a substrate. The integrated circuits mounted to the substrate are then encapsulated together in a protective housing, forming the package. Further examples of microelectronic packages include wafer level chip size packages, 3D packages, ceramic substrate packages, integrated circuit packages, solar cell packages, optoelectronic microelectronic fabrications, sensor image array packages, and display image array packages.

### EXAMPLES

In the examples below, experimental measurements are performed in order to illustrate the property improvements obtained in embodiments of polymer composites filled with graphite nano-platelet over other filler materials. It may be understood, however, that these examples are presented in order to demonstrate the superior performance of the nano-platelet filled composites and should in no way limit the scope of the invention.

### Example 1

### Thermal Conductivity

Thermal conductivity measurements of epoxy-composites with a carbon loading of approximately 0.054 volume fraction were performed in order to identify the thermal conductivity enhancements obtained using GNP-reinforcements. In order to assess the enhancement of thermal conductivity due to the use of GNPs as fillers, the GNP-composites are compared to comparable epoxy composites prepared with graphite microparticles. A dispersion of natural graphite flakes in acetone was prepared by grinding and sieving the graphite flakes, to reduce the particle size, followed by shear mixing for about 30 min and then bath ultrasonication for about 24 h. Subsequently, the dispersion was mixed with the epoxy and cured as discussed above in reference to the GNP composites. These unprocessed graphite composites possessed a length of approximately 30 μm and a thickness of approximately 10 μm.

Thermal conductivity measurements were performed as follows. Disc shaped samples having approximately 1 inch diameter were tested using an FOX50 (LaserComp Inc.) steady state heat flow instrument. The machine employs a two thickness measurement sample which substantially eliminates thermal contact resistance to the samples.

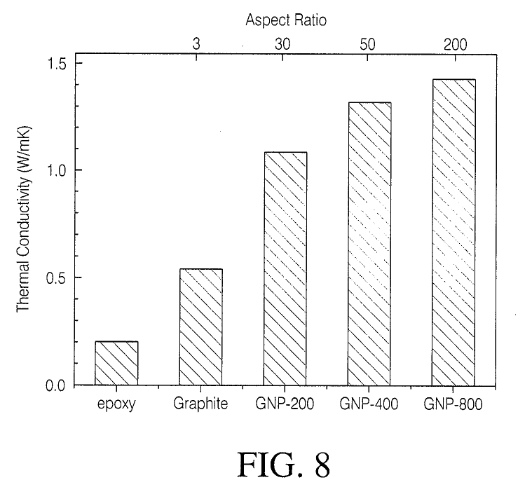

FIG. 8 illustrates the results of the thermal conductivity measurements. It can be seen that the fillers significantly improve the thermal conductivity of the epoxy composites. For example, graphite-epoxy composites demonstrate a thermal conductivity of about 0.54 W/mK. In contrast, the bulk epoxy alone demonstrates a thermal conductivity of about 0.20 W/mK.

The GNP fillers further improve the thermal conductivity of the epoxy. As illustrated in FIG. 8, all the GNP-filled composites exhibit significantly higher thermal conductivities than bulk epoxy or graphite-epoxy composites. Further, it is observed that the thermal conductivity of the GNP-epoxy materials is dependent on the exfoliation temperature. For example, the thermal conductivity of GNP-filled composites increases from approximately 1.1, to 1.3, to 1.4 W/mK, as the exfoliation temperature is increased from 200, to 400, to 800° C., respectively. In particular, the highest thermal conductivity, about 1.4 W/mK, measured is achieved in GNP-800. This value is about 360% higher than a simple graphite-epoxy composite. This GNP-800 material further compares favorably with currently available TIMs, which require about 10 times the volume fraction, 0.5-0.7, to achieve comparable thermal conductivities.

That the thermal conductivity enhancement is significantly increased at higher exfoliation temperatures indicates that the thermal conductivity is a function of the aspect ratio of the fillers. Advantageously, these results indicate that embodiments of the present disclosure may be utilized to control the thermal properties of epoxy or other polymer matrices using GNPs as filler.

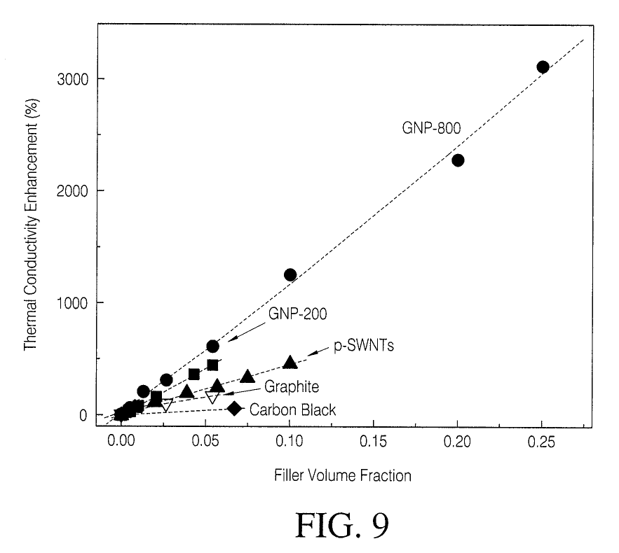

FIG. 9 shows the thermal enhancement as a function of the filler loading of composites prepared with carbon black, graphite, GNP-200, GNP-800, and purified single walled carbon nanotubes (p-SWNT). In general, the results confirm that the degree of thermal performance of the GNP composites increases with increasing degree of exfoliation, as illustrated in FIG. 8. Furthermore, the GNPs materials exhibit superior performance to both p-SWNTs and graphite.

The thermal enhancement of graphite is observed to be lower than that of p-SWNT, GNP-200, and GNP-800. Further, the GNPs perform better than p-SWNTs. The performance of the unfunctionalized GNP-800 exhibits extraordinary high thermal reinforcement as compared to the 1D SWNTs at all loadings. Presumably due to its low aspect ratio, graphite itself is much less effective than the GNPs, and the same is true of the 0-D, commercially available carbon black.

The efficiency of the GNP in increasing the thermal performance of epoxy composites is also compared with that of purified SWNT (p-SWNT) in FIG. 9. SWNTs perform better than the graphite and carbon black, likely because of the higher aspect ratio (about 100-1000 for the SWNTs) and more homogeneous dispersion in the polymer matrix. However, even the partially exfoliated GNP-200 material demonstrates a better thermal filler performance than the SWNTs, while the completely exfoliated GNP-800 nano-platelets show about 2.5 times the enhancement achieved with the SWNTs. In view of the similar intrinsic thermal conductivities and comparable aspect ratios of the two materials, the dominant thermal performance of the graphitic nano-platelets over carbon nanotubes is remarkable. These results indicate that other factors militate in favor of the GNPs, such as the dimensionality and rigidity of the nanoparticles and the thermal interface resistance between the nanomaterials and polymer matrix.

FIG. 9 further illustrates the non-linear dependence of the thermal enhancement on the SWNT loading, in contrast to GNP loadings. This is generally associated with the reduced effective aspect ratio obtained due to nanotube bending at high SWNT loadings. In contrast, the GNP materials demonstrate a nearly linear dependence of thermal enhancement on the filler volume fraction. This is believed due to the substantially more rigid 2D behavior of the graphite nano-platelets compared to the 1-D SWNTs.

Further enhancement in the thermal conductivity of graphite nano-platelet based epoxy composites may be obtained through improvements to the nano-platelet/epoxy interface bonding. In one example, this may be achieved through introducing chemical functionalities on the surface of the nano-platelets, similar to those envisioned in SWNT-based composites.

In further embodiments, the GNP fillers may be added to CNT-epoxy mixtures to create hybrid composites. The CNTs may comprise any carbon-nanotube materials known in the art, including, but not limited to, single-walled, double-walled, and multi-walled carbon nanotubes. For example, the GNP-800 filler can be added to the p-SWNT-epoxy to create a hybrid material (SWNT-GNP) having improved the thermal conductivity, as illustrated below in Table 1.

TABLE 1
Comparison of thermal and electrical conductivities
of various carbon-epoxy composite materials.

| | | Loading | Loading | Thermal | Electrical |
|---|---|---|---|---|---|
| | Density | (Mass) | (Volume) | Conductivity | Conductivity |
| Material | (g/cm³) | percent | percent | (W/mK) | (S/cm) |
| Epoxy | 1.17 | 100 | 100 | 0.21 | ~0 |
| Vulcan XC72 | 1.8 | 10.0 | 6.7 | 0.31 | 0.018 |
| Carbon Black | | | | | |
| p-SWNT | 1.4 | 10.0 | 8.5 | 0.87 | 0.033 |
| GNP-800 | 2.26 | 10.0 | 5.4 | 1.43 | 1.6 |
| GNP-800 | 2.26 | 17.6 | 10.0 | 2.71 | 2.2 |
| p-SWNT | 1.4 | 11.6 | 10.0 | 1.12 | 0.064 |
| GNP-800, | 1.4 (p-SWNT) | 14.1* (8.5, 5.4) | 10.0* (5.0, 5.0) | 2.93 | 0.35 |
| p-SWNT hybrid | 2.26 (GNP-800) | | | | |

*Denotes total loading of GNPs and p-SWNTs

A SWNT-GNP hybrid having approximately 0.05 vol. fraction of GNP-800 and approximately 0.05 vol. fraction of p-SWNTs shows better performance compared to individual loadings of approximately 0.1 volume fraction of either GNP-800 or p-SWNTs alone. The performance of p-SWNTs is substantially improved by the addition of GNP-800. Table 1 summarizes the thermal conductivities of GNP-800, p-SWNTs, and the hybrid material. The GNP-800 and the hybrid material perform much better than the commercial carbon black fillers.

### Example 2

### Electrical Conductivity

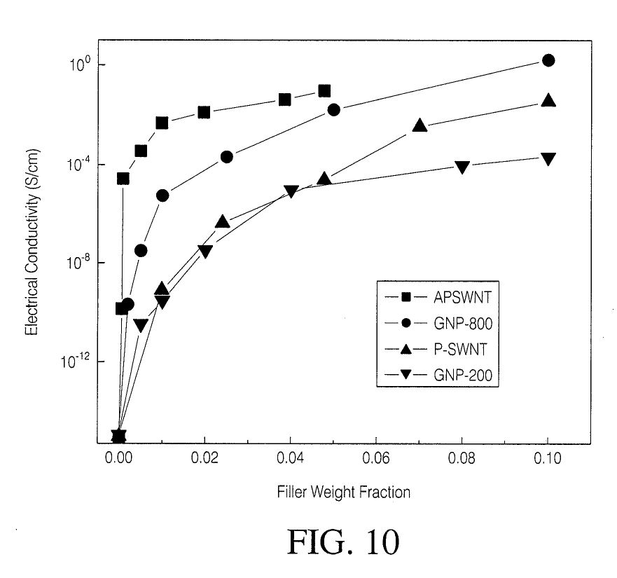

The electrical conductivity of the epoxy-composites with various weight fraction loadings of graphitic and SWNT materials was probed by four point measurement. FIG. 10 demonstrates that the incorporation of the graphite nano-platelets increases significantly the electrical conductivity of the epoxy composites and, furthermore, that the enhancement depends on the exfoliation temperature. The highest electrical conductivity was found in the GNP-800 composites. The electrical conductivity of GNP-800-epoxy composites was found to be significantly higher than that of the p-SWNT composites at substantially all loadings. Advantageously, this result illustrates that GNPs may provide an economical alternative to SWNTs. Further, at filler weight fractions of about 0.02 in GNP-800 and GNP-200, the electrical conductivity of the composite increases above about 10⁻⁸ S/cm, which is approximately the threshold for anti-static applications.

At loadings above about 0.05 weight fraction of GNP, the GNP-800 provides composites with high electrical conductivity. For example, the electrical conductivity of the GNP-800 epoxy reaches about 2.2 S/cm at about 0.1 volume fraction. Advantageously, these results indicate that GNP filled composites may be highly suitable for applications that require highly conductive composites, including electromagnetic interference (EMI) shielding and expansion fuses.

GNP thin films are also highly conductive. For example, the resistance of a GNP film having a thickness of about 300 nm was measured to be about 200 ohms, comparable to other carbon based films. The GNP thin films can be used in applications which include, but are not limited to, conductive coatings, transparent and conducting coatings and as lubrication coatings, where the thickness of the film is about 10 to 300 nm.

### Example 3

### Near-Infrared Applications

Embodiments of the present disclosure can also exhibit significant absorption properties at or about near-infrared range of the electromagnetic spectrum. As such, various features of the embodiments of the present disclosure can be combined with such absorption properties to allow implementations that include, for example, near-IR detectors.

In summary, embodiments of the present disclosure provide controlled exfoliation of graphite intercalation compounds which may be carried out at selected temperatures in an inert atmosphere to obtain exfoliated graphite having varied aspect ratios.

Other embodiments of the disclosure provide bulk scale stabilization of dispersions of individual graphite nano-platelets (GNPs) by utilizing shear mixing and ultrasonic treatments. The average aspect ratio of GNPs samples can be varied between about 30 and 200.

Further embodiments of the present disclosure provide few graphene layer GNPs, as compared to conventional single layer graphene sheets.

Additional embodiments of the present disclosure provide methods of in-situ polymerization of GNPs in the polymer matrix.

Further embodiments of the present disclosure provide graphite nano-platelet composites possessing superior thermal and electrical conductivity. For example, at about 0.1 volume fraction of GNPs, thermal conductivities of about 2.71 W/mK and electrical conductivities of about 2.2 S/cm are obtained, which far exceed the performance of current thermal interface materials and electrically conductive composites.

Another embodiment of the present disclosure provides a method of chemical modification of GNP edges or outer layers for independent control of thermal and electrical properties and for subsequent chemical functionalization and for substantially improved dispersion in solvents.

Further embodiments of the present disclosure provide transparent, highly conductive coatings for large area optoelectronic applications based on GNPs, particularly displays, light-emitting diodes and photovoltaics.

Additional embodiments of the present disclosure provide hybrid GNP and carbon nanotube materials for application as fillers in thermal interface materials, for advanced composites, and for transparent thin conductive coatings for large area optoelectronics.

Other embodiments of the present disclosure provide anti-frictional and lubrication systems incorporating GNPs due to their nanoscale size, smoothness and 2D graphitic structure.

Although the foregoing description has shown, described, and pointed out certain novel features of the present teachings, it will be understood that various omissions, substitutions, and changes in the form of the detail of the apparatus as illustrated, as well as the uses thereof, may be made by those skilled in the art, without departing from the scope of the present teachings. Consequently, the scope of the present teachings should not be limited to the foregoing discussion, but should be defined by the appended claims.

1. A method of fabricating graphite nano platelets, comprising:
providing a graphite compound;
intercalating the graphite compound by exposure to a plurality of acids;
exfoliating the intercalated graphite compound to form graphite nano platelets, wherein the exfoliation heating rate is varied so as to vary the length to thickness ratio of the graphite nano platelets; and
physically separating the graphite nano platelets.

2. The method of claim 1, wherein intercalated graphite compound is heated during exfoliation to a temperature less than or equal to about 1000° C., less than or equal to about 800° C., less than or equal to about 600° C., less than or equal to about 400° C., and about 200° C. over a time period of about 2 minutes.

3. The method of claim 1, wherein the intercalated graphite compound is heated during exfoliation at a rate less than or equal to about 500° C./min, less than or equal to about 400° C./min, less than or equal to about 300° C./min, less than or equal to about 200° C./min, and about 100° C./min during exfoliation.

4. The method of claim 1, wherein physically separating the graphite nano platelets comprises:
combining the graphite nano platelets with a solvent;
shear mixing the graphite nano platelet-solvent combination; and
ultrasonicating the graphite nano platelet-solvent combination at a sonic power ranging between approximately 45 W to 270 W for approximately 2 to 24 hours to obtain a graphite nano platelet dispersion.

5. The method of claim 1, wherein the volume of the graphite nano platelets is greater than about 100 times that of the particles of the graphite compound.

6. The method of claim 1, wherein the average thickness of the graphite nano platelets is about 250 times or less than that of the particles of the graphite compound.

7. The method of claim 1, wherein the graphite nano platelets possesses a length to thickness ratio ranging between approximately 30 to 200.

8. The method of claim 1, wherein the nano platelets correspond to stage 2 to stage 10 graphite.

9. The method of claim 1, further comprising treatment of the graphite nano platelets with an acid to introduce oxygen functional groups into the graphite nano platelets.

10. Graphite nano platelets, comprising:
an intercalated and thermally exfoliated graphite having an average length which varies between about 1.7 to 0.35 μm and an average thickness which varies between about 60 to 1.7 nm;
wherein the nano platelets are substantially separated from each other.

11. The graphite nano platelets of claim 10, wherein the nano platelets correspond to stage 2 to stage 10 graphite.

12. The nano platelets of claim 10, wherein the length to thickness ratio of the nano platelets ranges between approximately 30 to 200.

13. A lubricant comprising the graphite nano platelets of claim 10.

14. A graphite nano platelet composite, comprising:
a polymer; and
a plurality of graphite nano platelets comprising intercalated and thermally exfoliated graphite having an average length which varies between about 1.7 to 0.35 μm and an average thickness which varies between about 60 to 1.7 nm;
wherein the nano platelets are substantially separated from each other; and
wherein the loading fraction of the graphite nano platelets ranges between approximately 0.2 to 50 vol. %, based upon the total volume of the composite.

15. The composite of claim 14, wherein the loading fraction of the graphite nano platelets less than about 50 vol. %, less than about 40 vol. %, less than about 30 vol. %, less than about 20 vol. %, less than about 10 vol. %, less than about 5 vol. %, less than about 2 vol. %, and less than about 1 vol. %, based upon the total volume of the composite.

16. The composite of claim 14, wherein the thermal conductivity of the composite is greater than or equal to about 1.1 W/mK for loading fractions greater than or equal to about 5.4 vol. %.

17. The composite of claim 14, wherein the thermal conductivity of the composite is greater than or equal to about 1.1 W/mK for graphite nano platelets having an average ratio of length to width greater than about 30.

18. The composite of claim 14, wherein the thermal conductivity of the composite is greater than or equal to about 1.1 W/mK for graphite nano platelets thermally treated using a heating rate greater than or equal to about 100° C./min.

19. The composite of claim 14, wherein the electrical conductivity of the composite is greater than about 10⁻⁸ S/cm for loading fractions of graphite nano platelets greater than about 0.2 vol. %.

20. The composite of claim 14, further comprising carbon nanotubes.

21. The composite of claim 14, wherein the graphite nano platelets correspond to stage 2 to stage 10 graphite.

22. A thin film, comprising:
the graphite nano platelet composite of claim 14;
wherein the thin film has an average thickness of between approximately 10 nm to 300 nm.

23. A microelectronic package, comprising:
a substrate;
a thin film present on at least one surface of the substrate, the thin film comprising a plurality of graphite nano platelets, and
an integrated circuit mounted to at least one surface of the substrate.

24. The microelectronic package of claim 23, wherein the graphite nano platelets comprise intercalated and thermally exfoliated graphite having an average length which varies between about 1.7 to 0.35 μm and an average thickness which varies between about 60 to 1.7 nm.

25. The microelectronic package of claim 24, wherein the thin film is substantially transparent and possesses an average thickness of between approximately 10 nm to 300 nm.
